(19) United States
(12) Patent Application Publication
(10) Pub. No.: US 2025/0215563 A1
(43) Pub. Date: Jul. 3, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventor: Takashi YOKOGAWA, Toyama-shi (JP)

(73) Assignee: Kokusai Electric Corporation, Tokyo (JP)

(21) Appl. No.: 19/085,415

(22) Filed: Mar. 20, 2025

Related U.S. Application Data
(63) Continuation of application No. PCT/JP2022/035270, filed on Sep. 21, 2022.

(51) Int. Cl. C23C 16/455; C23C 16/34; C23C 16/44; C23C 16/52; H01L 21/285

(52) U.S. Cl. CPC C23C 16/45527; C23C 16/34; C23C 16/4408; C23C 16/45544; C23C 16/52; H01L 21/28568

(57) ABSTRACT

There is provided a technique that includes: (a) supplying a first processing gas to a substrate; (b) storing a second processing gas in a first reservoir while heating the second processing gas; (c) storing the second processing gas in a second reservoir different from the first reservoir while heating the second processing gas; (d) after (b), supplying the second processing gas from the first reservoir to the substrate; (e) after (c), supplying the second processing gas from the second reservoir to the substrate, (f) performing (a) and (d); (g) performing (a) and (e); and (h) forming a film on the substrate by performing a cycle that includes (f) and (g) a predetermined number of times.

### CROSS-REFERENCE TO RELATED APPLICATION

This application is based upon and claims the benefit of PCT International Application No. PCT/JP2022/035270, filed on Sep. 21, 2022, the entire contents of which are incorporated herein by reference.

### TECHNICAL FIELD

The present disclosure relates to a method of processing substrate, a method of manufacturing a semiconductor device, a substrate processing apparatus, and a recording medium.

### BACKGROUND

In the related art, as one of processes of manufacturing a semiconductor device, a process of supplying a processing gas to a plurality of substrates and forming a film on each of the substrates is performed.

A demand has existed for improved properties of films formed on a plurality of substrates.

### SUMMARY

Some embodiments of the present disclosure provide a technique capable of improving the properties of films formed on a plurality of substrates.

According to one embodiment of the present disclosure, there is provided a technique including (a) supplying a first processing gas to a substrate; (b) storing a second processing gas in a first reservoir while heating the second processing gas; (c) storing the second processing gas in a second reservoir different from the first reservoir while heating the second processing gas; (d) after (b), supplying the second processing gas from the first reservoir to the substrate; (e) after (c), supplying the second processing gas from the second reservoir to the substrate, (f) performing (a) and (d); (g) performing (a) and (e); and (h) forming a film on the substrate by performing a cycle that includes (f) and (g) a predetermined number of times.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in one embodiment of the present disclosure, in which the portion of the process furnace 202 is illustrated in a vertical sectional view.

FIG. 2 is a schematic configuration diagram of the vertical process furnace of the substrate processing apparatus suitably used in one embodiment of the present disclosure, in which the portion of the process furnace 202 is illustrated in a sectional view taken along line A-A in FIG. 1.

FIG. 3 is a schematic configuration diagram of a controller 121 of the substrate processing apparatus suitably used in one embodiment of the present disclosure, in which a control system of the controller 121 is illustrated in a block diagram.

FIG. 4 is a diagram showing a processing sequence according to one embodiment of the present disclosure.

FIG. 5 is a diagram showing a processing sequence according to modification 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of the Present Disclosure

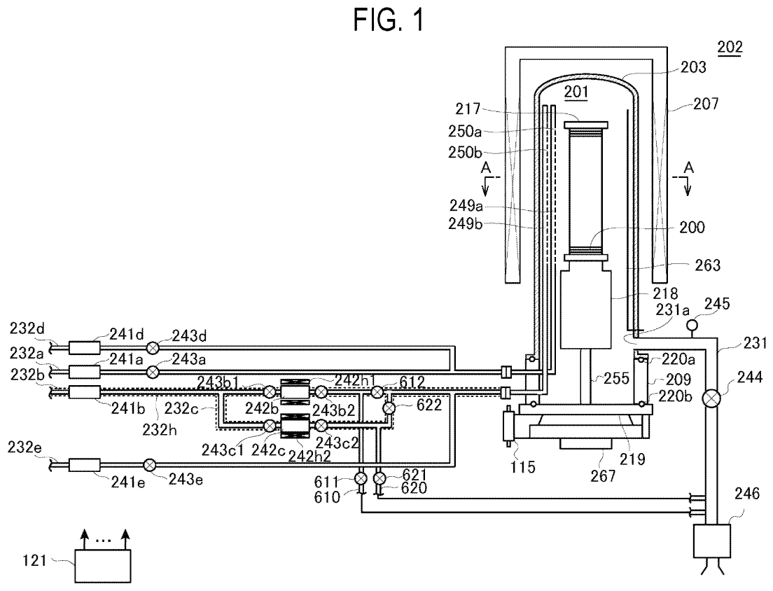

Hereinafter, one embodiment of the present disclosure will be described mainly with reference to FIGS. 1 to 4. The drawings used in the following description are all schematic. The dimensional relationship of each element on the drawings, the ratio of each element, and the like do not always match the actual ones. Further, even between the drawings, the dimensional relationship of each element, the ratio of each element, and the like do not always match.

### (1) Configuration of Substrate Processing Apparatus

As shown in FIG. 1, a process furnace 202 includes a heater 207 as a temperature adjustor (heater). The heater 207 has a cylindrical shape and is vertically installed by being supported by a holding plate. The heater 207 also functions as an activation mechanism that activates a gas with heat.

Inside the heater 207, a reaction tube 203 is arranged concentrically with the heater 207. The reaction tube 203 is made of a heat-resistant material such as, for example, quartz (SiO₂) or silicon carbide (SiC), and is formed in a cylindrical shape with an upper end thereof closed and a lower end thereof opened. Below the reaction tube 203, a manifold 209 is arranged concentrically with the reaction tube 203. The manifold 209 is made of a metallic material such as stainless steel (SUS) or the like, and is formed in a cylindrical shape with upper and lower ends thereof opened. The upper end of the manifold 209 is engaged with the lower end of the reaction tube 203 and is configured to support the reaction tube 203. An O-ring 220a as a seal member is provided between the manifold 209 and the reaction tube 203. The reaction tube 203 is installed vertically just like the heater 207. A process container (reaction container) is mainly composed of the reaction tube 203 and the manifold 209. A process chamber 201 is formed in the hollow portion of the process container. The process chamber 201 is configured to accommodate wafers 200 as substrates. The wafers 200 are processed in the process chamber 201.

Nozzles 249a and 249b as a first supply part and a second supply part are installed in the process chamber 201 so as to penetrate the side wall of the manifold 209. The nozzles 249a and 249b are also referred to as a first nozzle and a second nozzle, respectively. The nozzles 249a and 249b are respectively made of a heat-resistant material such as quartz or SiC. The nozzles 249a and 249b are connected to gas supply pipes 232a and 232b, respectively. The nozzles 249a and 249b are different nozzles, and the nozzles 249a and 249b are installed adjacent to each other.

On the gas supply pipe 232a, a mass flow controller (MFC) 241a, which is a flow rate controller (flow rate controller), and a valve 243a, which is an opening/closing valve, are installed sequentially from the upstream side of a gas flow. On the gas supply pipe 232b, an MFC 241b, a valve 243b1, a tank 242b, which is a first reservoir, a valve 243b2, and a valve 612, are installed sequentially from the upstream side of the gas flow. The upstream end of the gas supply pipe 232c is connected to the gas supply pipe 232b on the downstream side of the MFC 241b and on the upstream side of the valve 243b1. On the gas supply pipe 232c, a valve 243c1, a tank 242c, which is a second reservoir, a valve 243c2, and a valve 622, are installed sequentially from the upstream side of the gas flow. The downstream end of the gas supply pipe 232c is connected to the gas supply pipe 232b on the downstream side of the valve 612. A vent pipe 610 may be connected to the gas supply pipe 232b on the downstream side of the valve 243b2 and on the upstream side of the valve 612. A vent pipe 620 may be connected to the gas supply pipe 232c on the downstream of the valve 243c2 and on the upstream of the valve 622. Valves 611 and 621 are installed on the vent pipes 610 and 620, respectively. The vent pipes 610 and 620 are connected to an exhaust pipe 231 on the downstream side of an APC valve 244, which will be described later. A gas supply pipe 232d is connected to the gas supply pipe 232a on the downstream of the valve 243a. A gas supply pipe 232e is connected to the gas supply pipe 232b on the downstream of the valve 612. On the gas supply pipes 232d and 232e, MFCs 241d and 241e and valves 243d and 243e are respectively installed sequentially from the upstream side of the gas flow. The gas supply pipes 232a to 232e and the vent pipes 610, 620 are made of, for example, a metallic material such as stainless steel or the like. Although the example in which one MFC 241b is installed for the tanks 242b and 242c has been shown here, the present disclosure is not limited thereto. The gas supply system may be configured such that one MFC is installed for each of the tanks 242b and 242c.

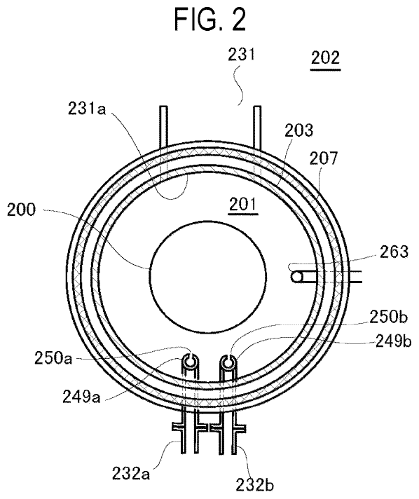

As shown in FIG. 2, the nozzles 249a and 249b are arranged in a space having an annular shape in a plan view between the inner wall of the reaction tube 203 and the wafers 200 and are installed to extend upward in the arrangement direction of the wafers 200 from the lower portion to the upper portion of the inner wall of the reaction tube 203. In other words, the nozzles 249a and 249b are respectively installed in a region horizontally surrounding a wafer arrangement region, in which the wafers 200 are arranged, on the lateral side of the wafer arrangement region so as to extend along the wafer arrangement region. Gas supply holes 250a and 250b for supplying gases are formed on the side surfaces of the nozzles 249a and 249b, respectively. The gas supply holes 250a and 250b are respectively opened so as to face the centers of the wafers 200 in a plan view and can supply gases toward the wafers 200. The gas supply holes 250a and 250b are formed from the lower portion to the upper portion of the reaction tube 203.

The tanks 242b and 242c are configured as gas tanks having a larger gas capacity than typical pipes, or as spiral pipes. By opening and closing the valves 243b1 and 243c1 on the upstream side of the tanks 242b and 242c and the valves 243b2 and 243c2 on the downstream side of the tanks 242b and 242c, the gases supplied from the gas supply pipes 232b and 232c can be temporarily filled (stored) in the tanks 242b and 242c, respectively, and the gases temporarily stored in the tanks 242b and 242c can be supplied into the process chamber 201.

By closing the valves 243b2, 243c1 and 243c2 and opening the valve 243b1, the gas whose flow rate has been adjusted by the MFC 241b can be temporarily stored in the tank 242b. After a predetermined amount of gas is stored in the tank 242b and the pressure in the tank 242b reaches a predetermined pressure, the valve 243b1 is closed and the valves 243b2 and 612 are opened, so that the high-pressure gas stored in the tank 242b can be supplied at once (in a short time) to the process chamber 201 via the gas supply pipe 232b and the nozzle 249b. In addition, by closing the valves 243b1, 243b2 and 243c2 and opening the valve 243c1, the gas whose flow rate has been adjusted by the MFC 241b can be temporarily stored in the tank 242c. After a predetermined amount of gas is stored in the tank 242c and the pressure in the tank 242c reaches a predetermined pressure, the valve 243c1 is closed and the valves 243c2 and 622 are opened, so that the high-pressure gas stored in the tank 242c can be supplied at once (in a short time) to the process chamber 201 through the gas supply pipes 232c and 232b and the nozzle 249b. Furthermore, by closing the valves 243b1 and 612 and opening the valves 243b2 and 611, the gas temporarily stored in the tank 242b can be bypassed without passing through the process chamber 201 and can be exhausted to the exhaust pipe 231 through the vent pipe 610. In addition, by closing the valves 243c1 and 622 and opening the valves 243c2 and 621, the gas temporarily stored in the tank 242c can be bypassed without passing through the process chamber 201 and can be exhausted to the exhaust pipe 231 through the vent pipe 620.

Heaters 242h1 and 242h2 serving as first and second heaters for heating the tanks 242b and 242c are provided around the outer periphery of the tanks 242b and 242c, respectively. By heating the tanks 242b and 242c with the heaters 242h1 and 242h2, the gases stored in the tanks 242b and 242c can be heated.

As shown in FIG. 1, for example, a ribbon-shaped heater 232h is wound around the outer periphery of the gas supply pipes 232b and 232c, for example, the outer periphery of the gas supply pipes 232b and 232c on the front stage (upstream side) and rear stage (downstream side) of the tanks 242b and 242c, as a third heater for heating them. By heating the gas supply pipes 232b and 232c on the front stage of the tanks 242b and 242c (e.g., the gas supply pipes 232b and 232c extending from the MFC 241b to the primary side (inlet) of the tanks 242b and 242c) with the heater 232h, the gases supplied to the tanks 242b and 242c can be preheated. In addition, by heating the gas supply pipes 232b and 232c downstream of the tanks 242b and 242c (e.g., the gas supply pipes 232b and 232c extending from the secondary side (outlet) of the tanks 242b and 242c to the process chamber 201) with the heater 232h, the gases supplied from the tanks 242b and 242c to the process chamber 201 can be heated.

A first processing gas as a precursor is supplied from the gas supply pipe 232a through the MFC 241a, the valve 243a, and the nozzle 249a into the process chamber 201. The first processing gas is used as one of film-forming agents.

A second processing gas as a reactant is supplied from the gas supply pipe 232b through the MFC 241b, the valve 243b1, the tank 242b, the valves 243b2 and 612, and the nozzle 249b into the process chamber 201. Furthermore, the second processing gas as a reactant is supplied from the gas supply pipe 232b through the MFC 241b, the gas supply pipe 232c, the valve 243c1, the tank 242c, the valves 243c2 and 622, and the nozzle 249b into the process chamber 201. The second processing gas is used as one of the film-forming agents.

An inert gas is supplied from the gas supply pipes 232d and 232e into the process chamber 201 via the MFCs 241d and 241e, the valves 243d and 243e, the gas supply pipes 232a and 232b, and the nozzles 249a and 249b, respectively. The inert gas acts as a purge gas, a carrier gas, a dilution gas, or the like.

A first supply system (precursor supply system) is mainly composed of the gas supply pipe 232a, the MFC 241a, and the valve 243a. A second supply system (first reactant supply system) is mainly composed of the gas supply pipe 232b, the MFC 241b, the valve 243b1, the tank 242b, and the valve 243b2. A third supply system (second reactant supply system) is mainly composed of the gas supply pipe 232c, the valve 243c1, the tank 242c, and the valve 243c2. The gas supply pipe 232b and the MFC 241b may be included in the third supply system. An inert gas supply system is mainly composed of the gas supply pipes 232d and 232e, the MFCs 241d and 241e, and the valves 243d and 243e. Each or all of the first to third supply systems is also referred to as a film-forming agent supply system.

Some or all of the above-described various supply systems may be configured as an integrated supply system 248 in which the valves 243a, 243b1, 243b2, 243c1, 243c2, 243d, 243e, 611, 612, 621 and 622, the MFCs 241a, 241b and 241d and the like are integrated. The integrated supply system 248 is connected to each of the gas supply pipes 232a to 232e and is configured so that the operations of supply of various gases into the gas supply pipes 232a to 232e, i.e., the opening and closing operations of the valves 243a, 243b1, 243b2, 243c1, 243c2, 243d, 243e, 611, 612, 621 and 622, the flow rate adjustment operation by the MFCs 241a, 241b and 241d, and the like are controlled by the controller 121 which will be described later. The integrated supply system 248 is formed of integral type or division type integrated units and may be attached to and detached from the gas supply pipes 232a to 232e and the like on an integrated unit basis. The integrated supply system 248 is configured so that the maintenance, replacement, expansion, and the like of the integrated supply system 248 can be performed on an integrated unit basis.

An exhaust port 231a for exhausting the atmosphere in the process chamber 201 is provided in the lower portion of the side wall of the reaction tube 203. As shown in FIG. 2, the exhaust port 23 la is provided at a position that faces the nozzles 249a and 249b (gas supply holes 250a and 250b) across the wafer 200 in a plan view. The exhaust port 231a may be provided to extend from the lower portion to the upper portion of the side wall of the reaction tube 203, i.e., along the wafer arrangement region. An exhaust pipe 231 is connected to the exhaust port 231a. A vacuum pump 246 as an evacuation device is connected to the exhaust pipe 231 via a pressure sensor 245 as a pressure detector (pressure detection part) for detecting the pressure inside the process chamber 201 and an APC (Auto Pressure Controller) valve 244 as a pressure regulator (pressure regulation part). The APC valve 244 is configured so that it can perform or stop vacuum evacuation of the interior of the process chamber 201 by being opened and closed in a state in which the vacuum pump 246 is operated. Furthermore, the APC valve 244 is configured so that it can regulate the pressure inside the process chamber 201 by adjusting the valve opening degree based on the pressure information detected by the pressure sensor 245 in a state in which the vacuum pump 246 is operated. An exhaust system is mainly constituted by the exhaust pipe 231, the APC valve 244 and the pressure sensor 245. The vacuum pump 246 may be included in the exhaust system.

A seal cap 219 as a furnace opening lid capable of airtightly closing the lower end opening of the manifold 209 is installed below the manifold 209. The seal cap 219 is made of a metallic material such as, for example, stainless steel or the like, and is formed in a disc shape. On the upper surface of the seal cap 219, there is installed an O-ring 220b as a seal member which abuts against the lower end of the manifold 209. Below the seal cap 219, there is installed a rotation mechanism 267 for rotating a boat 217 to be described later. A rotating shaft 255 of the rotation mechanism 267 is connected to the boat 217 through the seal cap 219. The rotation mechanism 267 is configured to rotate the wafers 200 by rotating the boat 217. The seal cap 219 is configured to be raised and lowered in the vertical direction by a boat elevator 115 as an elevating mechanism installed outside the reaction tube 203. The boat elevator 115 is configured as a transfer device (transfer mechanism) that loads and unloads (transfers) the wafers 200 into and out of the process chamber 201 by raising and lowering the seal cap 219.

A boat 217 as a substrate support tool is configured so as to support a plurality of wafers 200, for example, 25 to 200 wafers 200 in a horizontal posture and in multiple stages while vertically arranging the wafers 200 with the centers thereof aligned with each other, i.e., so as to arrange the wafers 200 at intervals. The boat 217 is made of a heat-resistant material such as, for example, quartz or SiC. A heat insulating part 218 made of a heat-resistant material such as, for example, quartz or SiC is installed at the bottom of the boat 217.

Inside the reaction tube 203, there is installed a temperature sensor 263 as a temperature detector. By adjusting the state of supply of electric power to the heater 207 based on the temperature information detected by the temperature sensor 263, the temperature inside the process chamber 201 becomes a desired temperature distribution. The temperature sensor 263 is installed along the inner wall of the reaction tube 203.

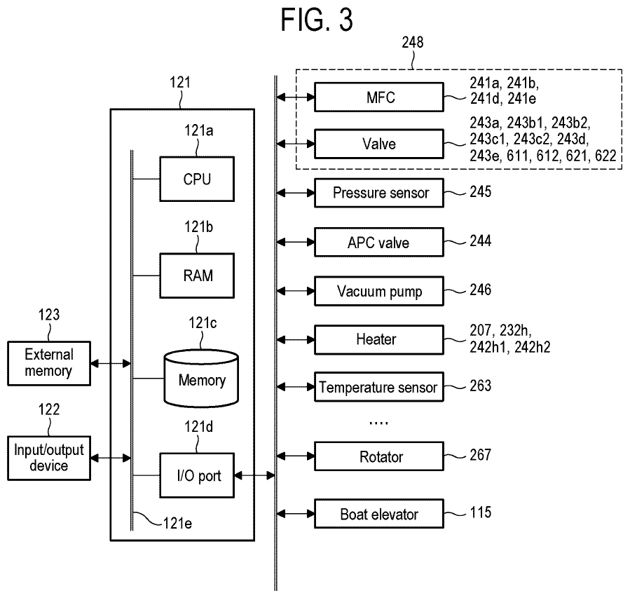

As shown in FIG. 3, the controller 121 as a controller (control means) is configured as a computer including a CPU (Central Processing Unit) 121a, a RAM (Random Access Memory) 121b, a memory device 121c and an I/O port 121d. The RAM 121b, the memory device 121c and the I/O port 121d are configured to exchange data with the CPU 121a via an internal bus 121e. An input/output device 122 configured as, for example, a touch panel or the like is connected to the controller 121. Further, an external memory device 123 may be connected to the controller 121.

The memory device 121c is composed of, for example, a flash memory, an HDD (Hard Disk Drive), an SSD (Solid State Drive), or the like. In the memory device 121c, there are readably stored a control program for controlling the operation of the substrate processing apparatus, a process recipe in which procedures and conditions of substrate processing to be described later are written, and the like. The process recipe is a combination of instructions for causing the controller 121 to have the substrate processing apparatus execute the respective procedures in a below-described substrate processing process so as to obtain a predetermined result. The process recipe functions as a program. Hereinafter, the process recipe, the control program, and the like are collectively and simply referred to as a program. Furthermore, the process recipe is also simply referred to as a recipe. When the term “program” is used herein, it may mean a case of including only the recipe, a case of including only the control program, or a case of including both the recipe and the control program. The RAM 121b is configured as a memory area (work area) in which programs, data and the like read by the CPU 121a are temporarily held.

The I/O port 121d is connected to the MFCs 241a, 241b and 241d, the valves 243a, 243b1, 243b2, 243c1, 243c2, 243d, 243e, 611, 612, 621 and 622, the pressure sensor 245, the APC valve 244, the vacuum pump 246, the temperature sensor 263, the heater 207, the rotation mechanism 267, the boat elevator 115, and the like.

The CPU 121a is configured to read and execute the control program from the memory device 121c and to read the recipe from the memory device 121c in response to an input of an operation command from the input/output device 122 or the like. The CPU 121a is configured to, according to the contents of the recipe thus read, control the flow rate adjustment operation for various gases by the MFCs 241a, 241b and 241d, the opening/closing operations of the valves 243a, 243b1, 243b2, 243c1, 243c2, 243d, 243e, 611, 612, 621 and 622, the opening/closing operation of the APC valve 244, the pressure regulation operation by the APC valve 244 based on the pressure sensor 245, the start and stop of the vacuum pump 246, the temperature adjustment operation of the heater 207 based on the temperature sensor 263, the rotation and the rotation speed adjustment operation of the boat 217 by the rotation mechanism 267, the raising and lowering operation of the boat 217 by the boat elevator 115, and the like.

The controller 121 may be configured by installing, in the computer, the above-described program recorded and stored in an external memory device 123. The external memory device 123 includes, for example, a magnetic disk such as an HDD or the like, an optical disk such as a CD or the like, a magneto-optical disk such as an MO or the like, a semiconductor memory such as a USB memory, an SSD or the like, and so forth. The memory device 121c and the external memory device 123 are configured as a computer readable recording medium. Hereinafter, the memory device 121c and the external memory device 123 are collectively and simply referred to as a recording medium. As used herein, the term “recording medium” may include only the memory device 121c, only the external memory device 123, or both. The provision of the program to the computer may be performed by using a communication means such as the Internet or a dedicated line without having to use the external memory device 123.

### (2) Substrate Processing Process

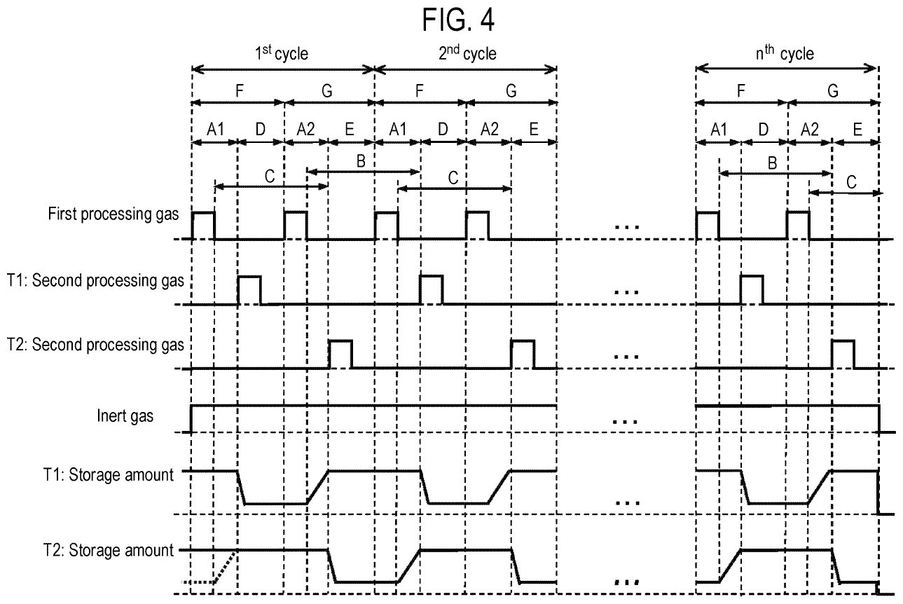

As one of processes of am a semiconductor device using the above-described substrate processing apparatus, a method of processing a substrate, i.e., an example of a processing sequence of forming a film on a wafer 200 as a substrate, will be described mainly with reference to FIG. 4. In the following description, the operation of each part constituting the substrate processing apparatus is controlled by the controller 121.

The processing sequence according to the present embodiment includes:
a step (step A) of supplying a first processing gas to a wafer 200;
a step (step B) of storing a second processing gas in a tank 242b while heating the second processing gas;
a step (step C) of storing the second processing gas in a tank 242c different from the tank 242b while heating the second processing gas;
a step (step D) of supplying the second processing gas from the tank 242b to the wafer 200 after step B; and
a step (step E) of supplying the second processing gas from the tank 242c to the wafer 200 after step C,
wherein a step (step F) of performing step A and step D, and a step (step G) of performing step A and step E are performed a predetermined number of times (n times where n is an integer equal to or greater than 1) to form a film on the wafer 200. Moreover, each step is performed in a non-plasma atmosphere.

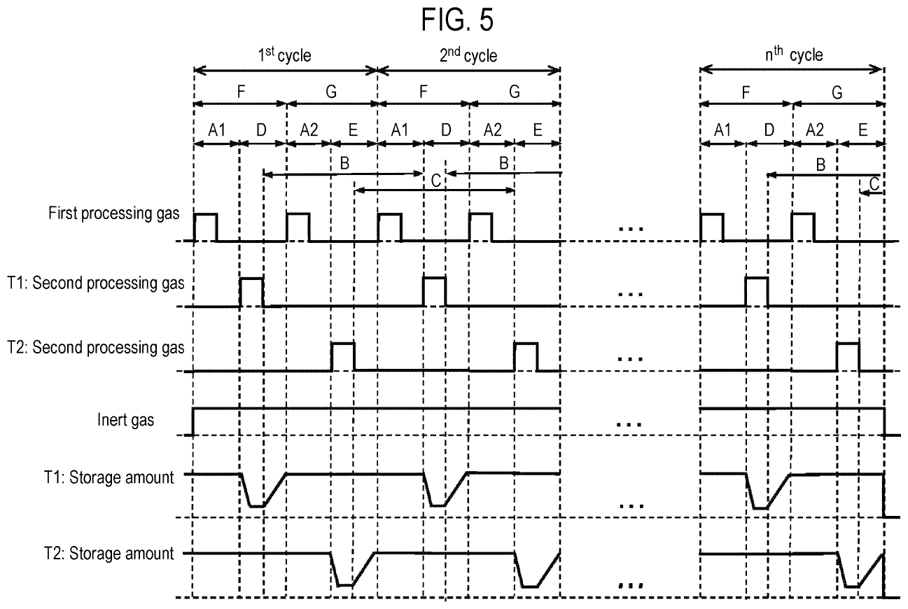

In FIG. 4, the execution period of step A performed in step F is denoted as A1 for the sake of convenience. In FIG. 4, the execution period of step A performed in step G is denoted as A2 for the sake of convenience. In FIG. 4, the execution periods of steps B to G are denoted as B to G, respectively, for the sake of convenience. In FIG. 4, the tanks 242b and 242c are denoted as T1 and T2, respectively, for the sake of convenience. The execution periods of the respective steps and the notations of the respective tanks are the same in FIG. 5, which shows a gas supply sequence of a modification described later.

In the following example, as shown in FIG. 4, a cycle including step F and step G is performed multiple times.

In this specification, the above-mentioned processing sequence may be expressed as follows for the sake of convenience. Similar notations will be used in the following description of modifications and other embodiments.

[(first processing gas→T1:second processing gas)→(first processing gas→T2:second processing gas)]×n

The term “wafer” used herein may refer to a wafer itself or a stacked body of a wafer and a predetermined layer or film formed on the surface of the wafer. The phrase “a surface of a wafer” used herein may refer to a surface of a wafer itself or a surface of a predetermined layer or the like formed on a wafer. The expression “a predetermined layer is formed on a wafer” used herein may mean that a predetermined layer is directly formed on a surface of a wafer itself or that a predetermined layer is formed on a layer or the like formed on a wafer. The term “substrate” used herein may be synonymous with the term “wafer.”

As used herein, the term “agent” includes at least one of a gaseous substance and a liquid substance. The liquid substance includes a mist-like substance. That is, the film-forming agents (the precursor and the reactant) may include a gaseous substance, a liquid substance such as a mist-like substance or the like, or both.

As used herein, the term “layer” includes at least one of a continuous layer and a discontinuous layer. The layer formed in each step described later may include a continuous layer, a discontinuous layer, or both.

### (Wafer Charging and Boat Loading)

After a plurality of wafers 200 are charged onto the boat 217 (wafer charging), as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. In this way, the wafers 200 are prepared inside the process chamber 201.

### (Pressure Regulation and Temperature Adjustment)

After the boat loading is completed, the inside of the process chamber 201, i.e., the space where the wafers 200 are present, is evacuated (depressurized) by the vacuum pump 246 so that a desired pressure (degree of vacuum) is achieved. At this time, the pressure inside the process chamber 201 is measured by the pressure sensor 245, and the APC valve 244 is feedback-controlled based on the measured pressure information. Further, the wafers 200 in the process chamber 201 are heated by the heater 207 so that they have a desired processing temperature. At this time, the power supply to the heater 207 is feedback-controlled based on the temperature information detected by the temperature sensor 263 so that the inside of the process chamber 201 has a desired temperature distribution. Further, the rotation of the wafers 200 by the rotation mechanism 267 is started. The evacuation of the process chamber 201, the heating of the wafers 200, and the rotation of the wafers 200 are all continued at least until the processing of the wafers 200 is completed.

### (Step of Charging Gas Into Reservoir)

In this step, the following two steps, namely step B and step C, are executed.

### [Step B]

In this step, the second processing gas is stored in the tank 242b while heating the second processing gas.

Specifically, while the valves 243b2, 243c1 and 243c2 are closed, the valve 243b1 is opened to allow the second processing gas to flow into the gas supply pipe 232b. The flow rate of the second processing gas is adjusted by the MFC 241b, and the second processing gas is supplied to the tank 242b and stored in the tank 242b. At this time, the gas supply pipe 232b extending from the MFC 241b to the inlet of the tank 242b is heated to a predetermined temperature by the heater 232h to preheat the second processing gas to be supplied to the tank 242b. After a predetermined amount of the second processing gas is stored in the tank 242b at a predetermined pressure, the valve 243b1 is closed to confine the second processing gas in the tank 242b. At this time, the tank 242b is heated to a predetermined temperature by the heater 242h1 to heat the second processing gas stored in the tank 242b. The volume of the tank 242b is preferably, for example, 300 to 2000 cc. In this case, the pressure inside the tank 242b when the second processing gas is confined in the tank 242b is preferably high, for example, 20000 Pa or more, and the amount of the second processing gas stored in the tank 242b (under elevated temperature and atmospheric pressure) is, for example, 120 to 3000 cc, preferably 120 to 2000 cc. Through this series of operations, the operation of storing (filling) the second processing gas in the tank 242b is completed (gas charging into the first reservoir).

By heating the second processing gas stored in the tank 242b, it becomes possible to supply the preheated second processing gas to the wafer 200 in step D described below. Furthermore, by preheating the second processing gas to be supplied to the tank 242b, it becomes possible to stabilize the temperature of the second processing gas in the tank 242b. As a result, it becomes possible to supply the second processing gas having a stabilized temperature to the wafer 200 in step D described below. These points hold true in step C described below.

This step is a preparation step for performing step D, which will be described later.

### [Step C]

In this step, the second processing gas is heated in the tank 242c while heating the second processing gas.

Specifically, while the valves 243b1, 243b2 and 243c2 are closed, the valve 243c1 is opened to allow the second processing gas to flow into the gas supply pipes 232b and 232c. The flow rate of the second processing gas is adjusted by the MFC 241b, and the second processing gas is supplied to the tank 242c and stored in the tank 242c. At this time, the gas supply pipes 232b and 232c extending from the MFC 241b to the inlet of the tank 242c are heated to a predetermined temperature by the heater 232h to preheat the second processing gas to be supplied to the tank 242c. After a predetermined amount of the second processing gas is stored in tank 242c at a predetermined pressure, the valve 243c1 is closed to confine the second processing gas in the tank 242c. At this time, the tank 242c is heated to a predetermined temperature by the heater 242h2 to heat the second processing gas stored in the tank 242c. The volume of the tank 242c is set to be the same as that of the tank 242b. Through this series of operations, the storage operation (filling operation) of the second processing gas in the tank 242c is completed (gas charging into the second reservoir).

This step is a preliminary step for performing step E, which will be described later.

### (Film Formation Step)

The following first and second film formation steps are executed in sequence.

### [First Film Formation Step]

In the first film formation step (hereinafter also referred to as step F), the following steps A1 and D are performed asynchronously, i.e., alternately without synchronization.

### [Step A1]

In this step, a first processing gas, i.e., a precursor (precursor gas), is supplied to the wafer 200 as a film-forming agent.

Specifically, the valve 243a is opened to allow the precursor to flow into the gas supply pipe 232a. The flow rate of the precursor is adjusted by the MFC 241a. The precursor is supplied into the process chamber 201 via the nozzle 249a, and is exhausted from the exhaust port 231a. At this time, the precursor is supplied to the wafer 200 from the lateral side thereof (precursor supply). At this time, the valves 243d and 243e may be opened to supply an inert gas into the process chamber 201 through the nozzles 249a and 249b.

The processing conditions when supplying the precursor in step A are exemplified as follows.
Processing temperature: 300 to 550 degrees C.
Processing pressure: 1 to 3990 Pa
Precursor supply flow rate: 0.1 to 2.0 slm
Inert gas supply flow rate (per gas supply pipe): 0.1 to 20 slm
Each gas supply time: 1 to 70 seconds, preferably 5 to 20 seconds

In this specification, the notation of a numerical range such as “300 to 550 degrees C.” means that a lower limit and an upper limit are included in the range. Therefore, for example, “300 to 550 degrees C.” means “300 degrees C. or more and 550 degrees C. or less.” The same applies to other numerical ranges. Further, the processing temperature in this specification means the temperature of the wafers 200 or the temperature inside the process chamber 201, and the processing pressure means the pressure inside the process chamber 201. Moreover, the processing time means the time during which the processing is continued. In addition, when the supply flow rate includes 0 slm, the 0 slm means a case where the substance (gas) is not supplied. The same applies to the following description.

Step A1 is performed under the above-mentioned processing conditions. For example, a gas containing titanium halide is supplied to the wafer 200 as a precursor, thereby forming a titanium (Ti)-containing layer containing a halogen on the wafer 200. In this specification, the Ti-containing layer containing a halogen is also simply referred to as a Ti-containing layer. The Ti-containing layer formed in step A1 is also referred to as a first Ti-containing layer.

After the first Ti-containing layer is formed on the wafer 200, the valve 243a is closed to stop the supply of the precursor into the process chamber 201. Then, the process chamber 201 is evacuated to remove gaseous substances remaining in the process chamber 201 from the inside of the process chamber 201. At this time, the valves 243d and 243e are opened to supply an inert gas into the process chamber 201 through the nozzles 249a and 249b. The inert gas supplied from the nozzles 249a and 249b acts as a purge gas, thereby purging the process chamber 201 (purging). The processing temperature when the purging is performed in this step is preferably the same as the processing temperature when the precursor is supplied.

As the precursor, for example, a Ti-containing gas containing titanium (Ti) as a first element constituting the film formed on the wafer 200 may be used. As the Ti-containing gas, for example, a gas containing a substance further containing at least one halogen element among chlorine (Cl), F, bromine (Br), and iodine (I), i.e., a halide (titanium halide), may be used. As the gas containing titanium halide, for example, a chlorotitanium-based gas containing Ti and Cl may be used. As the chlorotitanium-based gas, for example, a dichlorotitanium (TiCl₂) gas, a titanium tetrachloride (TiCl₄) gas, a trichlorotitanium (TiCl₃) gas, or the like may be used. As the precursor, in addition to the chlorotitanium-based gas, a fluoride-based gas such as a titanium tetrafluoride (TiF₄) gas or the like may also be used. As the precursor, one or more of these gases may be used.

As the inert gas, a nitrogen (N₂) gas or a rare gas such as an argon (Ar) gas, a helium (He) gas, a neon (Ne) gas, or a xenon (Xe) gas may be used. As the inert gas, one or more of these gases may be used. This also applies to each step described later.

After the first Ti-containing layer is formed, step C starts to perform step E, which will be described later. At this time, step C may start without exhausting the atmosphere in the tank 242c. That is, a predetermined amount of gas may be stored in the tank 242c before the start of step C. Moreover, as indicated by the broken line in FIG. 4, the tank 242c may be exhausted, and step C may be started during the first execution of step A1. That is, the storage sequence of T2 in the 1^{st} cycle shown in FIG. 4 may be stored in the same manner as in the 2^{nd} cycle or the nth cycle.

### [Step D]

After step A1 is completed, the second processing gas as the film-forming agent stored in tank 242b is supplied to the wafer 200, i.e., to the wafer 200 on which the first Ti-containing layer has been formed.

Now, an example will be described in which a nitriding agent (nitriding gas) containing nitrogen as a second element different from the first element is used as the second processing gas. This also applies to step E described later.

Specifically, while the valves 243b1, 243c1 and 243c2 are closed, the valves 243b2 and 612 are opened to allow the high-pressure nitriding agent stored in the tank 242b to flow into the process chamber 201 at once through the gas supply pipe 232b and the nozzle 249b. This causes the nitriding agent to be supplied to the wafer 200 at once (flash supply). At this time, the gas supply pipe 232b extending from the outlet of the tank 242b to the inside of the process chamber 201 is heated to a predetermined temperature by the heater 232h to suppress a decrease in the temperature of the nitriding agent supplied into the process chamber 201. Furthermore, at this time, the valves 243d and 243e may be opened to supply an inert gas into the process chamber 201 through each of the nozzles 249a and 249b. The flash supply is performed in any state from a state in which the exhaust system is substantially fully closed (the APC valve 244 is substantially fully closed) to a state in which the exhaust system is fully open. In this regard, substantially closed (substantially completely closed) includes a state in which the APC valve 244 is open by 0.1 to several percent, and a state in which, due to the performance of the APC valve 244, even if it is controlled to be 100% closed, a gas is still be exhausted to the exhaust system.

After a predetermined time has elapsed since the start of the flash supply, the valve 243b1 is opened while the valves 243b2 and 612 are kept open. The flow rate of the nitriding agent is adjusted by the MFC 241b, and the nitriding agent is supplied into the process chamber 201 through the gas supply pipe 232b, the tank 242b, and the nozzle 249b. This allows the nitriding agent to be supplied to the wafer 200 (non-flash supply). In this manner, in the non-flash supply of the nitriding agent, the nitriding agent is supplied into the process chamber 201 without being stored in the tank 242b in advance. In this case, the velocity of the nitriding agent on the wafer 200 is also smaller than that in the case of the flash supply. At this time, the gas supply paths from the MFC 241b to the process chamber 201, i.e., the gas supply pipe 232b and the tank 242b, are heated to a predetermined temperature by the heaters 232h and 242h1 to preheat the nitriding agent to be supplied into the process chamber 201. At this time, the valves 243d and 243e may be opened to supply an inert gas into the process chamber 201 through the nozzles 249a and 249b, respectively. In the non-flash supply of the nitriding agent, the APC valve 244 is not fully closed, but is set to, for example, a state between fully open and fully closed, so that the inside of the process chamber 201 is kept at a predetermined pressure.

The processing conditions when supplying the nitriding agent in step D are exemplified as follows.
Processing temperature: 300 to 550 degrees C.
Processing pressure (flash supply): 1 to 3990 Pa
Processing pressure (non-flash supply): 1 to 3990 Pa
Nitriding agent supply flow rate: 0.1 to 30 slm
Inert gas supply flow rate (per gas supply pipe): 0.1 to 30 slm
Nitriding agent supply time (flash supply): 1 to 10 seconds
Nitriding agent supply time (non-flash supply): 1 to 120 seconds

By performing step D under the above-mentioned processing conditions and supplying the nitriding agent to the wafer 200, a substitution reaction occurs between at least a part of the first Ti-containing layer formed on the wafer 200 in step A1 and the nitriding agent. During the substitution reaction, Ti contained in the first Ti-containing layer and nitrogen (N) contained in the nitriding agent are bonded to form a first titanium nitride layer (first TiN layer) on the wafer 200 as a layer containing Ti and N. That is, by supplying the nitriding agent to the wafer 200 under the above-mentioned processing conditions, a first TiN layer is formed on the wafer 200 by nitriding (modifying) the first Ti-containing layer. When forming the first TiN layer, impurities such as halogen contained in the first Ti-containing layer constitute a gaseous substance containing at least halogen during the process of the substitution reaction (modification reaction) of the first Ti-containing layer by the nitriding agent, and are discharged from the process chamber 201. As a result, the first TiN layer becomes a layer containing less impurities such as halogen and the like than the first Ti-containing layer formed in step A1. This holds true in step E described later.

In step D, when the nitriding agent is flush-supplied to the wafer 200, the nitriding agent is stored in the tank 242b in advance, heated, and then supplied into the process chamber 201. That is, the preheated nitriding agent is supplied to the wafer 200. Furthermore, when the nitriding agent is flush-supplied and non-flush-supplied to the wafer 200, the nitriding agent is preheated in the nitriding agent supply path before being supplied into the process chamber 201. This allows the reaction between the first Ti-containing layer and the nitriding agent to be started under uniform conditions, for example, under conditions where the nitriding agent is uniformly heated, over the entire wafer arrangement region. As a result, it is possible to improve the inter-plane uniformity (film thickness uniformity, film quality uniformity, etc.). Furthermore, by supplying the preheated nitriding agent to the wafer 200, it is possible to increase the reactivity between the first Ti-containing layer and the nitriding agent, and to promote these reactions. As a result, it is possible to improve the in-plane thickness uniformity and the step coverage of the first TiN layer formed on the wafer 200. In addition, it is possible to reduce the concentration of impurities such as a halogen and the like in the first TiN layer. By reducing the concentration of impurities in the first TiN layer, it is possible to obtain a film having a lower resistivity. In addition, by supplying the nitriding agent having a temperature stabilized in step B to the wafer 200, the reaction between the first Ti-containing layer and the nitriding agent can be started under more uniform conditions over the entire wafer arrangement region. As a result, it is possible to reliably improve the inter-plane uniformity. These points hold true in step E described below.

In step D, when the nitriding agent is first supplied to the wafer 200, the nitriding agent is stored in the tank 242b in advance and then supplied into the process chamber 201. That is, a large amount of the nitriding agent is supplied at once in a very short time (flash supply). In this case, compared to a case where the nitriding agent is supplied into the process chamber 201 without being stored in the tank 242b in advance (non-flash supply), it is possible to supply a larger amount of the nitriding agent to the surface of the wafer 200 located in the upper zone (top zone) of the wafer arrangement region in the wafer arrangement direction. In step D, the nitriding agent is flush-supplied and then non-flush-supplied to the wafer 200. In this case, compared to the flash supply, it is possible to supply a larger amount of the nitriding agent to the surface of the wafer 200 located in the lower zone (bottom zone) of the wafer arrangement region in the wafer arrangement direction. By performing the flash supply and non-flash supply of the nitriding agent in step D as described above, the amount of the nitriding agent supplied between the surfaces of the wafer 200 can be made uniform over the entire wafer arrangement region. As a result, it is possible to more reliably improve the inter-plane uniformity. This point holds true in step E described later.

After the first Ti-containing layer formed on the wafer 200 is nitrided and changed (converted) into the first TiN layer, the valves 243b1, 243b2, and 612 are closed to stop the supply of the nitriding agent into the process chamber 201. Then, gaseous substances remaining in the process chamber 201 are removed from the inside of the process chamber 201 by the same processing procedure and processing conditions as those for the purging in step A1 (purging). The processing temperature when performing the purging in this step is preferably the same as the processing temperature when supplying the nitriding agent.

As the nitriding agent, for example, a hydrogen nitride-based gas, which is a nitrogen (N)-containing gas, may be used. As the hydrogen nitride-based gas, for example, an ammonia (NH₃) gas may be used. As the nitriding agent, in addition to the NH₃ gas, for example, a hydrogen nitride-based gas such as a diazene (N₂H₂) gas or a hydrazine (N₂H₄) gas may be used. As the nitriding agent, one or more of these gases may be used. This point holds true in step E described later.

### [Second Film Formation Step]

In the second film formation step (hereinafter also referred to as step G), the following step A2 and step E are performed asynchronously, i.e., alternately without synchronization.

### [Step A2]

In this step, the first processing gas, i.e., the precursor (precursor gas), is supplied to the wafer 200, i.e., to the first TiN layer formed on the wafer 200. The processing procedure and processing conditions in step A2 are the same as those in step A1.

Step A2 is performed under the above-mentioned processing conditions. For example, a gas containing titanium halide is supplied as the precursor to the wafer 200, so that a Ti-containing layer is formed on the outermost surface of the wafer 200, i.e., on the first TiN layer formed on the wafer 200, in the same manner as in step A1. The Ti-containing layer formed in step A2 is also referred to as a second Ti-containing layer.

After the second Ti-containing layer is formed, the supply of the precursor into the process chamber 201 is stopped by the same processing procedure as in step A1. Then, gaseous substances remaining in the process chamber 201 are removed from the inside of the process chamber 201 by the same processing procedure and processing conditions as in the purging in step A1 (purging). The processing temperature when performing the purging in this step is preferably the same as the processing temperature when supplying the precursor.

After the second Ti-containing layer is formed, step B for executing step D in the next cycle is started. At this time, step B may be started without exhausting the atmosphere in the tank 242b. In other words, step B may be started while the atmosphere remains in the tank 242b. That is, step B may be started while the gas remains in the tank 242b. By starting step B while the atmosphere remains in the tank 242b, it is possible to reduce the amount of the gas supplied to the tank 242b. That is, it is possible to reduce the storage time in tank 242b. This processing holds true for the tank 242c.

### [Step E]

After step A2 is completed, the second processing gas, i.e., the nitriding agent, stored in the tank 242c is supplied to the wafer 200, i.e., the wafer 200 on which the second Ti-containing layer has been formed.

Specifically, while the valves 243b1, 243b2, and 243c1 are closed, the valves 243c2 and 622 are opened to allow the high-pressure nitriding agent stored in the tank 242c to flow into the process chamber 201 at once through the gas supply pipes 232c and 232b and the nozzle 249b. This allows the nitriding agent to be supplied to the wafer 200 at once (flash supply). At this time, the gas supply pipes 232b and 232c extending from the outlet of the tank 242c to the inside of the process chamber 201 are heated to a predetermined temperature by the heater 232h to suppress a decrease in the temperature of the nitriding agent supplied into the process chamber 201. After a predetermined time has elapsed since the start of the flash supply, the valve 243c1 is opened while the valves 243c2 and 622 are kept open. The flow rate of the nitriding agent is adjusted by the MFC 241b. The nitriding agent is supplied into the process chamber 201 through the gas supply pipes 232b and 232c, the tank 242c, and the nozzle 249b. This allows the nitriding agent to be supplied to the wafer 200 (non-flash supply). At this time, the gas supply paths from the MFC 241b to the process chamber 201, i.e., the gas supply pipes 232b and 232c and the tank 242c, are heated to a predetermined temperature by the heaters 232h and 242h2 to preheat the nitriding agent to be supplied into the process chamber 201. Other processing procedures are the same as those in step D. The processing conditions in this step are the same as those in step D.

By performing step E under the above-mentioned processing conditions and supplying the nitriding agent to the wafer 200, at least a portion of the second Ti-containing layer formed on the wafer 200 in step A2 is nitrided (modified) to form a second TiN layer.

After the second Ti-containing layer formed on the wafer 200 is nitrided and changed (converted) into the second TiN layer, the valves 243c1, 243c2, and 622 are closed to stop the supply of the nitriding agent into the process chamber 201. Then, gaseous substances remaining in the process chamber 201 are removed from the inside of the process chamber 201 by the same processing procedure and processing conditions as those for the purging in step A1 (purging). The processing temperature when performing the purging in this step is preferably the same as the processing temperature when supplying the nitriding agent.

### [Performing a Predetermined Number of Times]

By performing a cycle of performing the above-mentioned steps F and G asynchronously, i.e., alternately without synchronization, a predetermined number of times (n times where n is an integer of 1 or more), a titanium nitride film (TiN film) having a predetermined thickness and composed of a laminated film in which the first TiN layer and the second TiN layer are alternately laminated can be formed on the wafer 200. It is preferable to repeat the above-mentioned cycle multiple times. In other words, it is preferable that the thickness of the laminated film formed per cycle is set to be smaller than a desired thickness, and the above-mentioned cycle is repeated multiple times until the thickness of the film formed by laminating the laminated films reaches the desired thickness.

As described above, in step A1, after the first Ti-containing layer is formed, step C for executing step E is started. Furthermore, as described above, in step A2, after the second Ti-containing layer is formed, step B for executing step D in the next cycle is started. By alternately performing step F and step G, i.e., by supplying the nitriding agent using the tanks 242b and 242c alternately, it becomes possible to perform at least a part of step B and at least a part of step C in parallel. This makes it possible to secure a predetermined time as the residence time of the nitriding agent in the tanks 242b and 242c, i.e., the heating time. In addition, it becomes possible to shorten the cycle time and to improve the throughput.

Moreover, by supplying the nitriding agent using the tanks 242b and 242c alternately, it becomes possible to perform step C in parallel with a part of step F, and to perform step B in parallel with a part of step G. FIG. 4 shows an example in which step C is performed in parallel with step D, which is a part of step F, and step B is performed in parallel with step E, which is a part of step G. FIG. 4 also shows an example in which step D is started after the start of step C, and step E is started after the start of step B. This makes it possible to secure a sufficient time of residence of the nitriding agent in the tanks 242b and 242c, i.e., a sufficient heating time.

### (After-Purge and Atmospheric Pressure Restoration)

After the TiN film having a desired thickness is formed on the wafer 200, an inert gas as a purge gas is supplied into the process chamber 201 from each of the nozzles 249a and 249b, and is exhausted from the exhaust port 231a. As a result, the inside of the process chamber 201 is purged, and the gases, reaction by-products, and the like remaining in the process chamber 201 are removed from the inside of the process chamber 201 (after-purge). At this time, the valves 243b2, 243c2, 611, 612, 621 and 622 are opened, and the nitriding agent remaining in the tanks 242b and 242c is exhausted to the exhaust pipe 231 via the process chamber 201 and the vent pipes 610 and 620. Thereafter, the atmosphere inside the process chamber 201 is replaced with the inert gas (inert gas replacement), and the pressure inside the process chamber 201 is returned to the atmospheric pressure (atmospheric pressure restoration).

### (Boat Unloading and Wafer Discharging)

Thereafter, the seal cap 219 is lowered by the boat elevator 115, and the lower end of the manifold 209 is opened. The processed wafers 200 are then unloaded from the lower end of the manifold 209 to the outside of the reaction tube 203 while being supported by the boat 217 (boat unloading). The processed wafers 200 are taken out from the boat 217 after being unloaded to the outside of the reaction tube 203 (wafer discharging).

### (3) Effects of the Present Embodiment

According to the present embodiment, one or more of the following effects may be obtained.
(a) In steps D and E, by supplying the preheated nitriding agent to the wafer 200, the reaction between the first Ti-containing layer and the second Ti-containing layer formed on the wafer 200 and the nitriding agent can be started under uniform conditions over the entire wafer arrangement region. As a result, it is possible to improve the inter-plane uniformity (film thickness uniformity, film quality uniformity, etc.).
(b) In steps D and E, by supplying the preheated nitriding agent to the wafer 200, it is possible to enhance the reactivity between the first Ti-containing layer and the second Ti-containing layer formed on the wafer 200 and the nitriding agent, and to promote these reactions. As a result, it is possible to improve the properties of the film formed on the wafer 200. For example, it is possible to improve the in-plane thickness uniformity and the step coverage of the first TiN layer and the second TiN layer formed on the wafer 200. In addition, it is possible to reduce the impurity concentration in the first TiN layer and the second TiN layer, and it is possible to make the first TiN layer and the second TiN layer become a high-quality film having higher conductivity (low resistivity).
(c) By alternately performing step F and step G, i.e., by supplying the nitriding agent using the tanks 242b and 242c alternately, it becomes possible to perform at least a part of step B and at least a part of step C in parallel. This makes it possible to secure a predetermined time of residence of the nitriding agent in the tanks 242b and 242c, i.e., a predetermined heating time.
(d) By supplying the nitriding agent using the tanks 242b and 242c alternately, it becomes possible to perform step C in parallel with a part of step F and to perform step B in parallel with a part of step G. This makes it possible to secure a sufficient time of residence of the nitriding agent in the tanks 242b and 242c, i.e., a sufficient heating time.
(e) By heating the gas supply pipes 232b and 232c extending from the MFC 241b to the inlets of the tanks 242b and 242c to a predetermined temperature by the heater 232h to preheat the nitriding agent supplied to the tanks 242b and 242c, it is possible to stabilize the temperature of the nitriding agent in the tanks 242b and 242c. This makes it possible to supply the nitriding agent having a stabilized temperature to the wafer 200 in steps D and E. As a result, the reaction between the first Ti-containing layer, the second Ti-containing layer, and the nitriding agent can be started under more uniform conditions over the entire wafer arrangement region, and the inter-plane uniformity can be reliably improved.
(f) The above-mentioned effects can be obtained similarly even when a predetermined substance (gaseous substance, or liquid substance) is used by arbitrarily selecting it from the above-mentioned various precursors, various reactants, and various inert gases. The above-mentioned effects can be obtained even when the halogen contained in the first processing gas is any one of Cl, F, Br, and I.

### (4) Modifications

The processing sequence according to the present embodiment may be modified as shown in the following modifications. These modifications may be combined arbitrarily. Unless otherwise specified, the processing procedure and processing conditions in each step of each modification may be the same as the processing procedure and processing conditions in each step of the substrate processing sequence described above.

### (Modification 1)

As can be seen from the processing sequence shown in FIG. 5, after forming the first TiN layer in step D, step B, which is a preparation step for step D in the next cycle, may be performed from before the start of step G (step A2) to before the start of step D in step F performed in the next cycle. Furthermore, after forming the second TiN layer in step E, step C, which is a preparation step for step E in the next cycle, may be performed from before the start of step F (step A1) to before the start of step E in step G in the next cycle. FIG. 5 shows an example in which step B, which is a preparation step for step D in the next cycle, is started immediately after forming the first TiN layer in step D, this step B is performed until just before the start of step D in the next cycle, step C, which is a preparation step for step E in the next cycle, is started immediately after forming the second TiN layer in step E, and this step C is performed until just before the start of step E in the next cycle.

According to this modification, the same effects as those of the above-described embodiment can be obtained. Moreover, according to this modification, it is possible to more sufficiently secure the time of residence of the nitriding agent in the tanks 242b and 242c, i.e., the heating time. As a result, it is possible to reliably stabilize the temperature of the nitriding agent in the tanks 242b and 242c.

### (Modification 2)

After the supply of the nitriding agent in step D is completed, that is, after the first TIN layer is formed, the atmosphere in the tank 242b may be exhausted and the nitriding agent remaining in the tank 242b may be discharged. Furthermore, after the supply of the nitriding agent in step E is completed, that is, after the second TiN layer is formed, the atmosphere in the tank 242c may be exhausted and the nitriding agent remaining in the tank 242c may be discharged. Specifically, after the supply of the nitriding agent in steps D and E is completed, the atmosphere in the tanks 242b and 242c may be exhausted before the start of steps B and C for the next steps D and E, respectively.

Specifically, while the valves 243b1, 243c1, 612, and 622 are closed, the valves 243b2, 243c2, 611, and 621 are opened to discharge the nitriding agent remaining in the tanks 242b and 242c from the vent pipes 610 and 620 without passing through the process chamber 201. Furthermore, while the valves 243b1 and 243c1 are closed, the valves 243b2, 243c2, 612, and 622 are opened to discharge the nitriding agent remaining in the tanks 242b and 242c from the exhaust pipe 231 via the process chamber 201. Moreover, the exhaust without passing through the process chamber 201, that is, the exhaust from the vent pipes 610 and 620 and the exhaust via the process chamber 201 may both be performed. In this case, it is preferable to perform the exhaust from the vent pipes 610 and 620 after performing the exhaust through the process chamber 201. Furthermore, in this case, the exhaust from the vent pipes 610 and 620 and the exhaust through the process chamber 201 may be performed in parallel. It is preferable to perform the exhaust from the vent pipes 610 and 620 during the execution of step A2 which is performed immediately after the completion of step D, or during the execution of step A1 which is performed immediately after the completion of step E. When the wafer 200 is present in the process chamber 201, the exhaust of the atmosphere in the tanks 242b and 242c is preferably performed from the vent pipes 610 and 620.

This can reduce the amount of the nitriding agent decomposed in the tanks 242b and 242c. As a result, it is possible to uniformize the amount of the nitriding agent supplied to the wafer 200 in each cycle.

### (Modification 3)

When the heaters 242h1 and 242h2 are installed, the heater 232h may not be installed. That is, the tanks 242b and 242c may be heated by the heaters 242h1 and 242h2, respectively, to preheat the second processing gas supplied into the process chamber 201 in steps D and E. In this modification, a preheated nitriding agent can be supplied to the wafer 200 in steps D and E, and the same effects as those of the above-described embodiment can be obtained. As described above, it is preferable to install the heater 232h in that the second processing gas supplied to the tanks 242b and 242c can be preheated and the second processing gas supplied from the tanks 242b and 242c to the process chamber 201 can be heated.

### (Modification 4)

When the heater 232h is installed, the heaters 242h1 and 242h2 do not have to be installed. That is, in steps B and C, the gas supply pipes 232b and 232c may be heated to a predetermined temperature by the heater 232h, and the second processing gas supplied to the process chamber 201 may be preheated in steps D and E. In this modification, a preheated nitriding agent can be supplied to the wafer 200 in steps D and E, and the same effects as those of the above-described embodiment can be obtained. As described above, it is preferable to install the heaters 242h1 and 242h2 in that the second processing gas can be heated in the tanks 242b and 242c and the temperature of the second processing gas can be stabilized.

### (Modification 5)

The heater 232h may be installed at least in front of the tanks 242b and 242c in the gas supply pipes 232b and 232c. In this modification, the second processing gas supplied to the tanks 242b and 242c can be heated in steps B and C. As a result, a preheated nitriding agent can be supplied to the wafer 200 in steps D and E, and the same effects as those of the above-described embodiment can be obtained. Furthermore, in this modification, the second processing gas supplied to the tank 242b can be preheated. As a result, according to this modification, when the heaters 242h1 and 242h2 are installed, the temperature of the second processing gas can be stabilized in the tanks 242b and 242c.

### (Modification 6)

In step F, at least a part of the execution period of step A1 may overlap with at least a part of the execution period of step D. Furthermore, in step G, at least a part of the execution period of step A2 may overlap with at least a part of the execution period of step E. That is, the first processing gas and the second processing gas may be simultaneously supplied to the wafer 200 as a film-forming agent. According to this modification, the same effects as those of the above-described embodiment can be obtained.

### (Modification 7)

In steps D and E, the non-flash supply of the nitriding agent may be omitted. According to this variation, the same effects as those of the above-described embodiment can be obtained. However, as described above, in steps D and E, it is preferable to perform non-flash supply after the flash supply of the nitriding agent in that the amount of the nitriding agent supplied to between the surfaces of the wafers 200 can be uniformized over the entire wafer arrangement region, and the inter-plane uniformity can be more reliably improved.

### (Modification 8)

The number of tanks as reservoirs for storing the second processing gas is not limited to two, but may be set to any number of three or more. Furthermore, when there are three or more tanks, the storage and supply of the nitriding agent is performed by using the three or more tanks one after another. In other words, the term “alternately” in the present disclosure includes the case where three or more tanks are used one after another.

### Other Embodiments of the Present Disclosure

One embodiment of the present disclosure has been specifically described above. However, the present disclosure is not limited to the above-described embodiment, and various changes may be made without departing from the gist thereof.

For example, the present disclosure may be applied to a case where a film containing a semiconductor element such as silicon (Si) or germanium (Ge), or a metal element such as zirconium (Zr), hafnium (Hf), tantalum (Ta), aluminum (Al), molybdenum (Mo), tungsten (W) or ruthenium (Ru) as a first element is formed on a substrate. The processing procedure and processing conditions when supplying the film forming agent may be the same as those in each step of the above-described. In these cases, the same effects as those of the above-described embodiment can be obtained.

For example, the present disclosure may also be applied to a case where a film containing an element such as oxygen (O), carbon (C), nitrogen (N) or boron (B) as a second element is formed on a substrate. For example, the present disclosure may be applied to a case where the above-mentioned nitrogen-containing gas, an oxygen-containing gas such as a water vapor (H₂O gas), a hydrogen peroxide (H₂O₂) gas, a hydrogen (H₂) gas+oxygen (O₂) gas or an ozone (O₃) gas, a carbon-containing gas such as an ethylene (C₂H₄) gas, an acetylene (C₂H₂) gas or a propylene (C₃H₆) gas, a nitrogen- and carbon-containing gas such as a triethylamine ((C₂H₅)₃N) gas or a trimethylamine ((CH₃)₃N) gas, or a boron-containing gas such as a diborane (B₂H₆) gas or a trichloroborane (BCl₃) is used as a reactant to form a titanium oxide film (TiO film), a titanium oxide carbide film (TiOC film), a titanium oxide carbonitride film (TiOCN film), a titanium carbonitride film (TiCN film), a titanium boron nitride film (TiBN film), a titanium boron carbonitride film (TiBCN film), or the like, on a substrate by the above-described processing sequence. The processing procedure and processing conditions for supplying the film-forming agent may be the same as those in each step of the above-described embodiment. In these cases, the same effects as those of the above-described embodiment can be obtained.

In this specification, the description of two gases together, such as “H₂ gas+O₂ gas”, means a mixed gas of H₂ gas and O₂ gas. When supplying the mixed gas, the two gases may be mixed (pre-mixed) in a supply pipe and then supplied into the process chamber 201, or the two gases may be separately supplied into the process chamber 201 from different supply pipes and mixed (post-mixed) in the process chamber 201.

It is preferable that the recipes used for each process are prepared individually according to the content of a process, and recorded and stored in the memory device 121c via a telecommunications line or the external memory device 123. Then, when starting each process, it is preferable that the CPU 121a appropriately selects an appropriate recipe from among the plurality of recipes recorded and stored in the memory device 121c according to the content of a process. This makes it possible to form films of various film types, composition ratios, film qualities, and film thicknesses with good reproducibility using a single substrate processing apparatus. In addition, the burden on the operator can be reduced, and each process can be started quickly while avoiding operational errors.

The above-mentioned recipes are not limited to being newly created, but may be prepared by, for example, modifying existing recipes that have already been installed in a substrate processing apparatus. When modifying the recipes, the modified recipes may be installed in the substrate processing apparatus via a telecommunications line or a recording medium on which the recipes are recorded. Alternatively, the input/output device 122 provided in an existing substrate processing apparatus may be operated to directly modify existing recipes already installed in the substrate processing apparatus.

In the above-described embodiment, there has been described the example in which a film is formed using a batch-type substrate processing apparatus that processes a plurality of substrates at a time. The present disclosure is not limited to the above-described embodiment, but may also be suitably applied to, for example, a case where a film is formed using a single-substrate type substrate processing apparatus that processes one or several substrates at a time. Furthermore, in the above-described embodiment, there has been described the example in which a film is formed using the substrate processing apparatus having a hot wall type process furnace. The present disclosure is not limited to the above-described embodiment, but may be suitably applied to a case where a film is formed using a substrate processing apparatus having a cold wall type process furnace.

Even when using these substrate processing apparatuses, each process may be performed under the same processing procedures and processing conditions as in the above-described embodiment and modifications, and the same effects as in the above-described embodiment and modifications may be obtained.

The above-described embodiment and modifications may be used in combination as appropriate. The processing procedures and processing conditions at this time may be the same as, for example, the processing procedures and processing conditions of the above-described embodiment and modifications.

According to the present disclosure in some embodiments, it is possible to improve the properties of films formed on a plurality of substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing substrate, comprising:
(a) supplying a first processing gas to a substrate;
(b) storing a second processing gas in a first reservoir while heating the second processing gas;
(c) storing the second processing gas in a second reservoir different from the first reservoir while heating the second processing gas;
(d) after (b), supplying the second processing gas from the first reservoir to the substrate;
(e) after (c), supplying the second processing gas from the second reservoir to the substrate,
(f) performing (a) and (d);
(g) performing (a) and (e); and
(h) forming a film on the substrate by performing a cycle that includes (f) and (g) a predetermined number of times.

2. The method of claim 1, wherein at least a part of (b) and at least a part of (c) are performed simultaneously.

3. The method of claim 1, wherein (d) is performed after (c) is started, and
wherein (e) is performed after (b) is started.

4. The method of claim 1, further comprising:
(i) exhausting an atmosphere in the first reservoir after supplying the second processing gas in (d) is completed; and
(j) exhausting an atmosphere in the second reservoir after supplying the second processing gas in (e) is completed.

5. The method of claim 4, wherein in (i) and (j), the exhausting through a space in which the substrate is present and the exhausting without going through the space are performed, respectively.

6. The method of claim 1, wherein the predetermined number of times of (h) is a plurality of times,
wherein (b) is started without exhausting the atmosphere in the first reservoir after (d), and
wherein (c) is started without exhausting the atmosphere in the second reservoir.

7. The method of claim 1, wherein the predetermined number of times of (h) is a plurality of times,
wherein (c) is performed simultaneously with at least a part of (f), and
wherein (b) is performed in parallel with at least a part of (g).

8. The method of claim 7, wherein (c) is performed from prior to a start of (f) in a cycle of (h), until prior to a start of (e) in (g) to be performed in a next cycle of (h), and
(b) is performed from prior to a start of (g) in a cycle of (h), until prior to a start of (d) in (f) to be performed in a next cycle of (h).

9. The method of claim 1, wherein in (b), the second processing gas is heated by a first heater installed in the first reservoir, and in (c), the second processing gas is heated by a second heater installed in the second reservoir.

10. The method of claim 9, wherein in both of (b) and (c), the second processing gas is heated by a third heater installed in a front side of the first reservoir and the second reservoir.

11. The method of claim 1, wherein in both of (b) and (c), the second processing gas is heated by a third heater installed in a front side of the first reservoir and the second reservoir.

12. The method of claim 1, wherein the first processing gas is a precursor gas.

13. The method of claim 1, wherein the second processing gas is a reactant.

14. The method of claim 12, wherein the second processing gas is a reactant.

15. A method of manufacturing a semiconductor device, comprising the method of claim 1.

16. A substrate processing apparatus, comprising:
a first supply system configured to supply a first processing gas to a substrate;
a second supply system configured to supply a second processing gas stored in a first reservoir to the substrate;
a third supply system configured to supply a second processing gas stored in a second reservoir different from the first reservoir to the substrate;
a first heater configured to heat the first reservoir;
a second heater configured to heat the second reservoir; and
a controller configured to be capable of controlling the first supply system, the second supply system, the third supply system, a first heater, and a second heater to perform:
(a) supplying the first processing gas to the substrate;
(b) storing the second processing gas in the first reservoir while heating the second processing gas;
(c) storing the second processing gas in the second reservoir different while heating the second processing gas;
(d) after (b), supplying the second processing gas from the first reservoir to the substrate;
(e) after (c), supplying the second processing gas from the second reservoir to the substrate,
(f) performing (a) and (d);
(g) performing (a) and (e); and
(h) forming a film on the substrate by performing a cycle that includes (f) and
(g) a predetermined number of times.

17. A non-transitory computer-readable recording medium storing a program that causes, by a computer, a substrate processing apparatus to perform a process comprising:
(a) supplying a first processing gas to a substrate;
(b) storing a second processing gas in a first reservoir while heating the second processing gas;
(c) storing the second processing gas in a second reservoir different from the first reservoir while heating the second processing gas;
(d) after (b), supplying the second processing gas from the first reservoir to the substrate;
(e) after (c), supplying the second processing gas from the second reservoir to the substrate,
(f) performing (a) and (d);
(g) performing (a) and (e); and
(h) forming a film on the substrate by performing a cycle that includes (f) and (g) a predetermined number of times.
